(19) United States
(12) Patent Application Publication
(10) Pub. No.: US 2025/0291248 A1
(43) Pub. Date: Sep. 18, 2025

(54) PHOTOSENSITIVE RESIN COMPOSITION, PHOTOSENSITIVE RESIN LAYER AND SEMICONDUCTOR DEVICE USING THE SAME

(71) Applicant: SAMSUNG SDI CO., LTD., Yongin-si (KR)

(72) Inventors: Heekyoung KANG, Suwon-si (KR); Sang Soo KIM, Suwon-si (KR); Taek-Jin BAEK, Suwon-si (KR); Mingyum KIM, Suwon-si (KR); Inkeol PARK, Suwon-si (KR); Jinhee KANG, Suwon-si (KR); Taesoo KIM, Suwon-si (KR); Chungbeum HONG, Suwon-si (KR); Byeongwook PARK, Suwon-si (KR)

(21) Appl. No.: 18/948,048

(22) Filed: Nov. 14, 2024

(30) Foreign Application Priority Data
Mar. 18, 2024 (KR) 10-2024-0037080

(51) Int. Cl. G03F 7/038; C08K 5/33; H01L 21/027

(52) U.S. Cl. CPC G03F 7/0384; C08K 5/33; H01L 21/0271

(57) ABSTRACT

A photosensitive resin composition, a photosensitive resin layer manufactured utilizing the photosensitive resin composition, and a semiconductor device including the photosensitive resin layer are provided. The photosensitive resin composition includes: (A) at least one resin selected from among a polyimide precursor and a polybenzoxazole precursor; (B) a photopolymerizable compound; (C) a photoinitiator represented by Chemical Formula 1; and (D) a solvent.

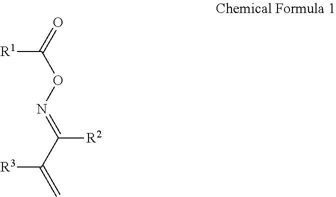

### CROSS-REFERENCE TO RELATED APPLICATION

The present application claims priority to and the benefit of Korean Patent Application No. 10-2024-0037080, filed on Mar. 18, 2024, in the Korean Intellectual Property Office, the entire disclosure of which is incorporated herein by reference.

### BACKGROUND

### 1. Field

One or more embodiments of the present disclosure relate to a photosensitive resin composition, a photosensitive resin layer manufactured using the photosensitive resin composition, and a semiconductor device including the photosensitive resin layer.

### 2. Description of the Related Art

A method of sealing a semiconductor device with an epoxy resin composition is currently in commercial use to protect the device from external factors such as moisture and/or mechanical impact (e.g., for the purpose of protecting the semiconductor device from external environments such as moisture and/or mechanical impact and/or the like). Traditionally, semiconductor device sealing involves cutting (dicing) a wafer to manufacture semiconductor chips, followed by packing each individual semiconductor chip (e.g., chip unit). Recently, however, a process has been developed where the packaging is performed first at the wafer or panel level (e.g., in a wafer state or a panel state that is larger than the semiconductor chips) and then the packaged unit is cut (diced) into individual semiconductor chips (e.g., pack into the semiconductor chips). The traditional method is generally referred to as chip scale packaging (CSP), while the newer process is known as wafer level packaging (WLP) and panel level packaging (PLP).

The wafer level packaging (WLP)/panel level packaging (PLP) has advantages of a higher process yield than the chip scale packaging (CSP) and a smaller semiconductor-mounting space due to its thin package thickness. However, the wafer level packaging (WLP) or the panel level packaging (PLP) has a larger filming area than the chip scale packaging (CSP) of sealing individual chips and thus a problem and/or issue of significantly generating warpage due to a thermal expansion rate difference between wafer or panel and a sealing material. The warpage, if ever occurs, may affect a yield and wafer handling in the subsequent process. In addition, the wafer level packaging (WLP) or the panel level packaging (PLP) currently uses a liquid type or kind epoxy resin or silicone resin as a main sealant but has problems/issues of having a low content (e.g., amount) of an inorganic filler in a liquid type or kind composition and low reliability of a semiconductor package after a sealing as the resin also uses liquid monomolecules.

Accordingly, development of an insulating layer for a redistribution layer (RDL), which may achieve little warpage, even if (e.g., when) the wafer level packaging (WLP) or the panel level packaging (PLP) is applied, and excellent or suitable reliability, is desired or required.

In order to meet the requirement, development of a photosensitive resin composition for forming an insulating layer for a redistribution layer is ongoing. In general, a photosensitive polyimide resin composition, in which photosensitivity is imparted to a polyimide resin itself, is mainly used. The photosensitive polyimide resin composition may simplify a pattern forming process. However, the photosensitive polyimide resin composition, which is used to form an insulating layer (cured layer) for a redistribution layer, has a problem and/or issue of deteriorating anti-corrosion and chemical resistance.

When a photosensitive resin composition is used for a semiconductor circuit passivation layer, a polyimide (PI) resin or a polybenzoxazole (PBO) resin is used as a key element to secure an elongation rate which is critical for reliability and film characteristics such as a glass transition temperature (Tg). Accordingly, a photosensitive resin composition including the above resin needs to be used with other photocrosslinkable monomers, photopolymerization initiators, and/or the like. to secure excellent or suitable passivation layer characteristics. It is still essential that this composition leaves no residues to ensure excellent pattern formation, sensitivity characteristics, and storage stability for over two weeks at room temperature (e.g., it is still desired to have no residues to realize an excellent or suitable pattern, excellent or suitable sensitivity characteristics, and storage stability for more than two weeks at room temperature). In addition, as electronic devices are down-sized (e.g., miniaturized) and made more functional (e.g., multifunctional), the resin film also is desired or required for high resolution, thereby, requiring a resin composition capable of forming one or more suitable pattern shapes. In order to meet the high-resolution requirements, various proposals have been made regarding the photopolymerization initiator included in the resin composition, with a highly sensitive photoinitiator being utilized.

However, the use of a highly sensitive photoinitiator presents challenges, as even minor variations in its concentration can significantly impact pattern shapes, making it difficult to control and reducing the exposure margin. In addition, as a thickness of the resin film increases, there may be discrepancies in photo-curability between the upper and lower portions of the film (e.g., a difference in photo-curability in upper/lower portions of the film). Consequently, while an appropriate critical dimension (CD) may be achieved, the lower portion of the film may be penetrated by the developing solution, leading to issues such as pattern lifting or reverse taper. In other words, the use of a highly sensitive photoinitiator makes it difficult to control pattern shapes and reduces the exposure margin, and as the resin film thickness increases, discrepancies in photo-curability between the upper and lower portions may lead to issues such as pattern lifting or reverse taper (e.g., the lower portion may be penetrated by the developing solution, leading to issues such as pattern lifting or reverse taper).

### SUMMARY

One or more aspects of embodiments of the present disclosure are directed toward a photosensitive resin composition that is excellent or suitable in handling, may easily control pattern formation, and may be implemented at high resolution by using a photoinitiator having a specific structure of the present disclosure. In other words, one or more aspects of embodiments of the present disclosure are directed toward a photosensitive resin composition that is easy to handle, allows for precise control of pattern formation, and can achieve high resolution by utilizing a photoinitiator with a specific structure.

One or more aspects of embodiments of the present disclosure are directed toward a photosensitive resin layer manufactured using the photosensitive resin composition.

One or more aspects of embodiments of the present disclosure are directed toward a semiconductor device including the photosensitive resin layer.

Additional aspects will be set forth in part in the description which follows and, in part, will be apparent from the description, or may be learned by practice of the presented embodiments of the disclosure.

According to one or more embodiments of the present disclosure, a photosensitive resin composition includes: (A) at least one resin selected from among a polyimide precursor and a polybenzoxazole precursor; (B) a photopolymerizable compound; (C) a photoinitiator represented by Chemical Formula 1; and (D) a solvent.

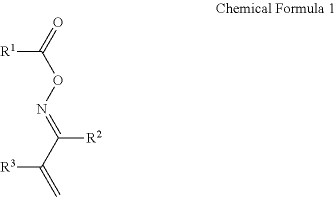

In Chemical Formula 1,

R¹ to R³ may each independently be hydrogen, a substituted or unsubstituted C1 to C20 alkyl group, a substituted or unsubstituted C1 to C20 alkoxy group, a substituted or unsubstituted C3 to C20 cycloalkyl group, or a substituted or unsubstituted C6 to C20 aryl group, provided that R¹ to R³ are not all hydrogens at the same time.

In one or more embodiments, R¹ and R³ may be the same as each other.

In one or more embodiments, R¹ and R³ may each independently be a substituted or unsubstituted C6 to C20 aryl group.

In one or more embodiments, R² may be a substituted or unsubstituted C1 to C20 alkyl group or a substituted or unsubstituted C3 to C20 cycloalkyl group.

In one or more embodiments, the photoinitiator represented by Chemical Formula 1 may include at least one selected from among compounds represented by Chemical Formula 1-1 to Chemical Formula 1-3.

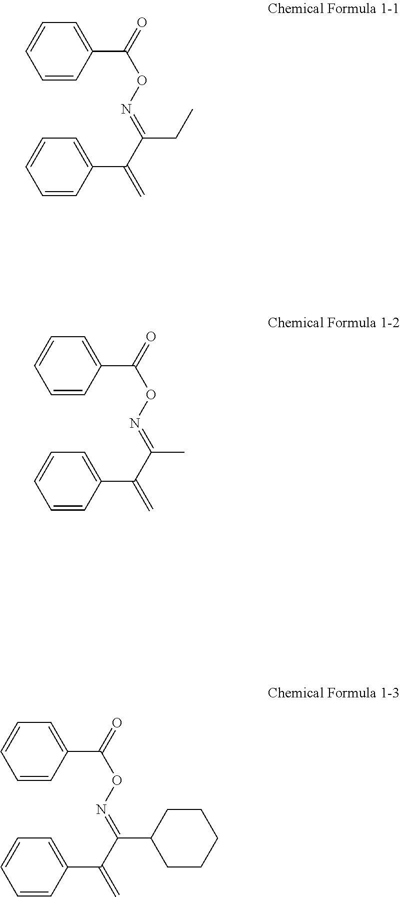 [SMILES: C=C(/C(CC)=N/OC(=O)c1ccccc1)c1ccccc1 ; C=C(/C(C)=N/OC(=O)c1ccccc1)c1ccccc1 ; C=C(/C(=N/OC(=O)c1ccccc1)C1CCCCC1)c1ccccc1]

The photoinitiator represented by Chemical Formula 1 may be included in an amount of about 1 part by weight to about 5 parts by weight based on 100 parts by weight of the photosensitive resin composition.

In one or more embodiments, the photosensitive resin composition may further include a photosensitizer.

The photosensitizer may be included in a smaller amount than the photoinitiator represented by Chemical Formula 1 in the photosensitive resin composition.

In one or more embodiments, the photosensitive resin composition further includes an antioxidant, and the antioxidant may be included in a smaller amount than the photosensitizer.

In one or more embodiments, the photosensitive resin composition may include about 20 parts by weight to about 40 parts by weight of the resin, about 1 part by weight to about 10 parts by weight of the photopolymerizable compound, about 1 part by weight to about 5 parts by weight of the photoinitiator, and about 40 parts by weight to about 80 parts by weight of the solvent based on 100 parts by weight of the photosensitive resin composition.

In one or more embodiments, the photosensitive resin composition may further include an additive such as a diacid, an alkanolamine, a leveling agent, a silane coupling agent, a surfactant, an epoxy compound, a thermal latent acid generator, and/or a (e.g., any suitable) combination thereof.

The photosensitive resin composition may be a negative type or kind photosensitive resin composition.

One or more embodiments of the present disclosure provide a photosensitive resin layer manufactured using the photosensitive resin composition.

The photosensitive resin layer may be a semiconductor redistribution layer insulating layer.

In one or more embodiments of the present disclosure, a semiconductor device includes the photosensitive resin layer.

Other embodiments of the disclosure are included in the following detailed description.

The photosensitive resin composition according to one or more embodiments includes a photoinitiator with a specific structure of the present disclosure, so that pattern formation may be easily controlled or selected and a high-resolution pattern may be implemented.

### BRIEF DESCRIPTION OF THE DRAWINGS

FIG. 1 is a focused ion beam (FIB) image of a cross-section of a cured layer prepared by curing the photosensitive resin composition according to Example 1 of the present disclosure.

FIG. 2 is a focused ion beam (FIB) image of a cross-section of a cured layer prepared by curing the photosensitive resin composition according to Example 2 of the present disclosure.

FIG. 3 is a focused ion beam (FIB) image of a cross-section of a cured layer prepared by curing the photosensitive resin composition according to Example 3 of the present disclosure.

FIG. 4 is a focused ion beam (FIB) image of a cross-section of a cured layer prepared by curing the photosensitive resin composition according to Example 4 of the present disclosure.

FIG. 5 is a focused ion beam (FIB) image of a cross-section of a cured layer prepared by curing the photosensitive resin composition according to Comparative Example 1 of the present disclosure.

FIG. 6 is a focused ion beam (FIB) image of a cross-section of a cured layer prepared by curing the photosensitive resin composition according to Comparative Example 2 of the present disclosure.

FIG. 7 is a focused ion beam (FIB) image of a cross-section of a cured layer prepared by curing the photosensitive resin composition according to Comparative Example 3 of the present disclosure.

### DETAILED DESCRIPTION

Hereinafter, embodiments of the disclosure will be described in more detail. However, these embodiments are mere examples, the present disclosure is not limited thereto and the present disclosure is defined by the scope of appended claims and equivalents thereof.

As used herein, if (e.g., when) a specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C7 to C20 arylalkyl group, “alkylene group” refers to a C1 to C20 alkylene group, “arylene group” refers to a C6 to C20 arylene group, “alkylarylene group” refers to a C7 to C20 alkylarylene group, “heteroarylene group” refers to a C3 to C20 heteroarylene group, and “alkoxy group” refers to a C1 to C20 alkoxy group.

As used herein, if (e.g., when) a specific definition is not otherwise provided, “substituted” refers to replacement of at least one hydrogen of a compound or a group by a substituent selected from among a halogen (fluorine (F), chlorine (Cl), bromine (Br), or iodine (I)), a C1 to C20 alkyl group substituted with a halogen such as a trifluoromethyl group, a hydroxyl group, a C1 to C20 alkoxy group, a nitro group, a cyano group, an amine group, an imino group, an azido group, an amidino group, a hydrazino group, a hydrazono group, a carbonyl group, a carbamoyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, and/or a (e.g., any suitable) combination thereof.

As used herein, if (e.g., when) a specific definition is not otherwise provided, “hetero” refers to inclusion of at least one heteroatom selected from among N, O, S, and P, in the chemical formula.

As used herein, if (e.g., when) a specific definition is not otherwise provided, “(meth)acrylate” refers to both “acrylate” and “methacrylate.”

As used herein, if (e.g., when) a definition is not otherwise provided, the term “combination” refers to mixing or copolymerization. Also, the term “copolymerization” refers to block copolymerization, alternating copolymerization, or random copolymerization, and the term “copolymer” refers to a block copolymer, an alternating copolymer, or a random copolymer.

As used herein, if (e.g., when) a specific definition is not otherwise provided, an unsaturated bond includes not only multiple bonds between carbon and carbon atoms, but also those bonds containing other types of atoms, such as a carbonyl bond and an azo bond.

In the chemical formula of the present disclosure, unless a specific definition is otherwise provided, hydrogen is boned at the position if (e.g., when) a chemical bond is not drawn where supposed to be given.

As used herein, if (e.g., when) a definition is not otherwise provided, refers to a linking part between the same or different atoms, or chemical formulas.

A photosensitive resin composition according to one or more embodiments includes: (A) at least one resin selected from among a polyimide precursor and a polybenzoxazole precursor; (B) a photopolymerizable compound; (C) a photoinitiator represented by Chemical Formula 1; and (D) a solvent.

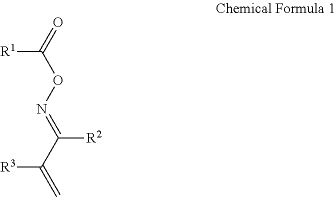

In Chemical Formula 1,

R¹ to R³ may each independently be hydrogen, a substituted or unsubstituted C1 to C20 alkyl group, a substituted or unsubstituted C1 to C20 alkoxy group, a substituted or unsubstituted C3 to C20 cycloalkyl group or a substituted or unsubstituted C6 to C20 aryl group, provided that R¹ to R³ are not all hydrogens at the same time.

Hereinafter, each component of the photosensitive resin composition will be described in more detail.

### (A) Resin

The resin used in the photosensitive resin composition according to one or more embodiments may be a polyamic acid or polyamic ester-based resin (polyimide precursor), and the polyamic acid or polyamic ester-based resin may include a structural unit represented by Chemical Formula 2.

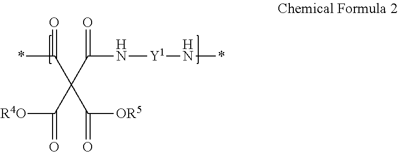

In Chemical Formula 2,
X¹ may be a moiety derived from a dianhydride monomer,
Y¹ may be a moiety derived from a diamine monomer, and
R⁴ and R⁵ may each independently be a substituted or unsubstituted C1 to C20 alkyl group, a substituted or unsubstituted C3 to C20 cycloalkyl group, a substituted or unsubstituted C6 to C20 aryl group, or a substituted or unsubstituted C2 to C20 heterocyclic group.

In one or more embodiments, R⁴ and R⁵ may each independently be a C1 to C20 alkyl group that is substituted or unsubstituted with a (meth)acrylate group at the terminal end thereof, a C3 to C20 cycloalkyl group that is substituted or unsubstituted with a (meth)acrylate group at the terminal end thereof, a C6 to C20 aryl group that is substituted or unsubstituted with a (meth)acrylate group at the terminal end thereof, or a C2 to C20 heterocyclic group that is substituted or unsubstituted with a (meth)acrylate group at the terminal end thereof.

The polyamic acid or polyamic ester-based resin including the structural unit represented by Chemical Formula 2 may be used together with the photoinitiator represented by Chemical Formula 1, so that the heat resistance stability of the photosensitive resin composition according to one or more embodiments may be very easily improved and in addition, it is easy to greatly improve developability by applying the photosensitive resin composition to a negative type or kind composition. In other words, using the polyamic acid or polyamic ester-based resin with the structural unit from Chemical Formula 2 alongside the photoinitiator from Chemical Formula 1 may significantly enhance the heat resistance stability and developability of the photosensitive resin composition, especially when applied to a negative type composition.

In general, photosensitive resin compositions including a resin with a closed ring structure have the problem and issue of quickly gelling under harsh conditions, but the polyamic acid or polyamic ester-based resin including structural units represented by Chemical Formula 2 is used with a photoinitiator represented by Chemical Formula 1, and thus the photosensitive resin composition according to one or more embodiments may gel very slowly even under harsh conditions and have excellent or suitable heat resistance stability.

For example, in one or more embodiments, the polyamic acid or polyamic ester-based resin including the structural unit represented by Chemical Formula 2 may be a polymer between a dianhydride monomer and a diamine monomer.

For example, in one or more embodiments, the diamine monomer may be represented by Chemical Formula 2-2 or Chemical Formula 2-3.

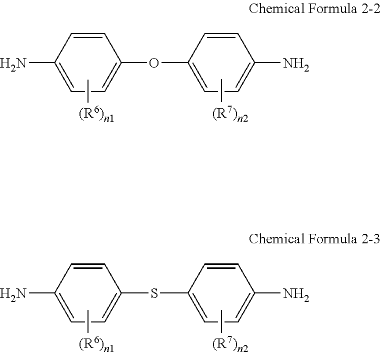

In Chemical Formula 2-2 and Chemical Formula 2-3,
R⁶ and R⁷ may each independently be a halogen, a hydroxyl group, a substituted or unsubstituted C1 to C20 alkyl group, or a substituted or unsubstituted C1 to C20 alkoxy group, and
n1 and n2 may each independently be an integer in a range of 0 to 4.

For example, in one or more embodiments, the dianhydride monomer may include a monomer represented by Chemical Formula 2-1, but embodiments of the present disclosure are not necessarily limited thereto.

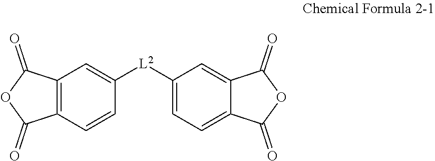

In Chemical Formula 2-1,

L² may be a single bond, *—O—*, *—S—*, *—C≡C—*, *—C(═O)—*, *—C(═O)O—*, *−NR⁰—* (wherein R⁰ may be a substituted or unsubstituted C1 to C10 alkyl group), a substituted or unsubstituted C1 to C20 alkylene group, a substituted or unsubstituted C6 to C20 arylene group, a substituted or unsubstituted C2 to C20 heterocyclic linking group, or a (e.g., any suitable) combination thereof.

For example, in one or more embodiments, L² may be a substituted or unsubstituted C1 to C20 alkylene group, or a C1 to C20 alkylene group substituted or unsubstituted with a trifluoroalkyl group.

A weight average molecular weight (Mw) of the polyamic acid or polyamic ester-based resin may be about 3,000 g/mol to about 300,000 g/mol. If the weight average molecular weight of the polyamic acid or polyamic ester-based resin is within the above range, sufficient physical properties may be obtained, and the solubility in organic solvents is improved, making it easy to handle. In the present disclosure, the weight average molecular weight (Mw) of a polymer/resin may be measured by gel permeation chromatography (GPC).

The resin may be included in an amount of about 20 parts by weight to about 40 parts by weight, for example about 25 parts by weight to about 35 parts by weight, based on 100 parts by weight of the photosensitive resin composition. If the resin is included within the above range, it may be advantageous and beneficial in terms of increasing the resolution of the pattern.

The resin used in the photosensitive resin composition according to one or more embodiments may be a polybenzoxazole-based resin.

The polybenzoxazole-based resin may include a structural unit represented by Chemical Formula 41 and the polyimide precursor may include a structural unit represented by Chemical Formula 51.

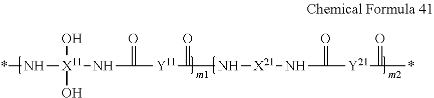

In Chemical Formula 41,
X¹¹ and X²¹ are each independently a substituted or unsubstituted quadrivalent C6 to C30 aromatic organic group,
Y¹¹ and Y²¹ are each independently a substituted or unsubstituted C6 to C30 aromatic organic group, a substituted or unsubstituted divalent C1 to C30 aliphatic organic group, or a substituted or unsubstituted divalent C3 to C30 alicyclic organic group, and
m1 is an integer of 2 to 1000, m2 is an integer of 0 to 500, and m1/(m1+m2)>0.5.

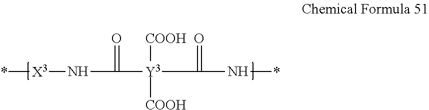

In Chemical Formula 51,
X³ is a substituted or unsubstituted divalent C6 to C30 aromatic organic group, a substituted or unsubstituted divalent C1 to C30 aliphatic organic group, or a substituted or unsubstituted divalent C3 to C30 alicyclic organic group, and
Y³ is a substituted or unsubstituted quadrivalent C6 to C30 aromatic organic group, a substituted or unsubstituted quadrivalent C1 to C30 aliphatic organic group, or a substituted or unsubstituted quadrivalent C3 to C30 alicyclic organic group.

In Chemical Formula 41, X¹¹ and X²¹ may be an aromatic organic group and may be a moiety derived from an aromatic diamine.

Examples of the aromatic diamine may be at least one selected from among 3,3′-diamino-4,4′-dihydroxybiphenyl, 4,4′-diamino-3,3′-dihydroxybiphenyl, bis(3-amino-4-hydroxyphenyl) propane, bis(4-amino-3-hydroxyphenyl) propane, bis(3-amino-4-hydroxyphenyl) sulfone, bis(4-amino-3-hydroxyphenyl) sulfone, 2,2-bis(3-amino-4-hydroxyphenyl)-1,1,1,3,3,3-hexafluoropropane, 2,2-bis(4-amino-3-hydroxyphenyl)-1,1,1,3,3,3-hexafluoropropane, 2,2-bis(3-amino-4-hydroxy-5-trifluoromethylphenyl)hexafluoropropane, 2,2-bis(3-amino-4-hydroxy-6-trifluoromethylphenyl)hexafluoropropane, 2,2-bis(3-amino-4-hydroxy-2-trifluoromethylphenyl)hexafluoropropane, 2,2-bis(4-amino-3-hydroxy-5-trifluoromethylphenyl)hexafluoropropane, 2,2-bis(4-amino-3-hydroxy-6-trifluoromethylphenyl)hexafluoropropane, 2,2-bis(4-amino-3-hydroxy-2-trifluoromethylphenyl)hexafluoropropane, 2,2-bis(3-amino-4-hydroxy-5-pentafluoroethylphenyl)hexafluoropropane, 2-(3-amino-4-hydroxy-5-trifluoromethylphenyl)-2-(3-amino-4-hydroxy-5-pentafluoroethylphenyl)hexafluoropropane, 2-(3-amino-4-hydroxy-5-trifluoromethylphenyl)-2-(3-hydroxy-4-amino-5-trifluoromethylphenyl)hexafluoropropane, 2-(3-amino-4-hydroxy-5-trifluoromethylphenyl)-2-(3-hydroxy-4-amino-6-trifluoromethylphenyl)hexafluoropropane, 2-(3-amino-4-hydroxy-5-trifluoromethylphenyl)-2-(3-hydroxy-4-amino-2-trifluoromethylphenyl)hexafluoropropane, 2-(3-amino-4-hydroxy-2-trifluoromethylphenyl)-2-(3-hydroxy-4-amino-5-trifluoromethylphenyl)hexafluoropropane, and 2-(3-amino-4-hydroxy-6-trifluoromethylphenyl)-2-(3-hydroxy-4-amino-5-trifluoromethylphenyl)hexafluoropropane, but are not limited thereto.

Examples of X¹¹ and X²¹ may be a functional group represented by Chemical Formula 61 or Chemical Formula 71, but is not limited thereto.

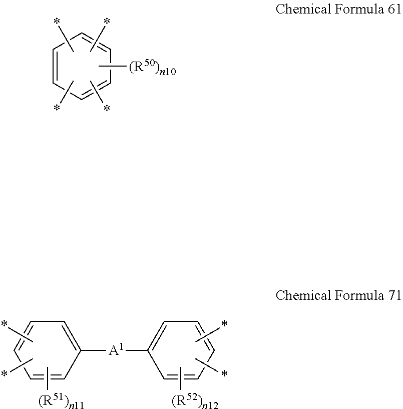

In Chemical Formula 61 and Chemical Formula 71,
A¹ is a single bond, O, CO, CR⁴⁷R⁴⁸, SO₂, or S wherein R⁴⁷ and R⁴⁸ are each independently a hydrogen atom or a substituted or unsubstituted C1 to C30 alkyl group, specifically a C1 to C30 fluoroalkyl group,
R⁵⁰ to R⁵² are each independently a substituted or unsubstituted C1 to C30 alkyl group, a substituted or unsubstituted C1 to C30 carboxyl group, a hydroxyl group, or a thiol group, and
n10 is an integer of 0 to 2, provided that n11 and n12 are each independently an integer of 0 to 3.

In Chemical Formula 41, Y¹¹ and Y²¹ may each independently be a divalent aromatic organic group, a divalent aliphatic organic group, or a divalent alicyclic organic group and may be a moiety of dicarboxylic acid or a moiety of a dicarboxylic acid derivative. Specifically, Y¹¹ and Y²¹ may each independently be a divalent aromatic organic group or a divalent alicyclic organic group.

Specific examples of the dicarboxylic acid derivative may be 4,4′-oxydibenzoylchloride, diphenyloxydicarbonyl dichloride, bis(phenylcarbonylchloride)sulfone, bis(phenylcarbonylchloride)ether, bis(phenylcarbonylchloride)phenone, phthaloyl dichloride, terephthaloyl dichloride, isophthaloyl dichloride, dicarbonyl dichloride, diphenyloxydicarboxylate dibenzotriazole, or a combination thereof, but are not limited thereto.

Examples of Y¹¹ and Y²¹ may be functional groups represented by Chemical Formula 81, Chemical Formula 91, and Chemical Formula 100, but are not limited thereto.

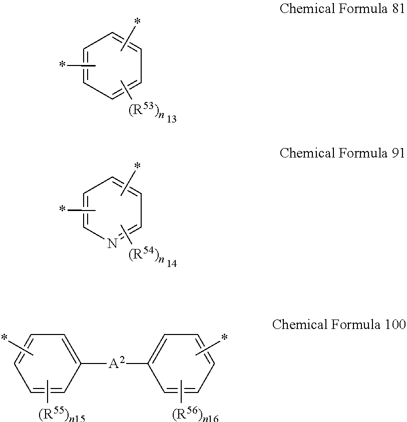

In Chemical Formula 81, Formula 91, and Chemical Formula 100,
R⁵³ to R⁵⁶ are each independently a substituted or unsubstituted C1 to C30 alkyl group,
n13 and n14 are each independently an integer of 0 to 4, n15 and n16 are each independently an integer of 0 to 3, and
A² is a single bond, O, CR⁴⁷R⁴⁸, CO, CONH, S, or SO₂, wherein R⁴⁷ and R⁴⁸ are each independently a hydrogen atom or a substituted or unsubstituted C1 to C30 alkyl group, specifically a C1 to C30 fluoroalkyl group.

In Chemical Formula 51, X³ is a divalent aromatic organic group, a divalent aliphatic organic group, or a divalent organic group. Specifically, X³ is a divalent aromatic organic group or a divalent alicyclic organic group.

Specifically, X³ may be a moiety derived from an aromatic diamine, an alicyclic diamine, or a silicon diamine. Herein, the aromatic diamine, the alicyclic diamine, and the silicon diamine may be used alone or in a combination of one or more.

Examples of the aromatic diamine may be 3,4′-diaminodiphenylether, 4,4′-diaminodiphenylether, 3,4′-diaminodiphenylmethane, 4,4′-diaminodiphenylmethane, 4,4′-diaminodiphenylsulfone, 4,4′-diaminodiphenylsulfide, benzidine, m-phenylenediamine, p-phenylenediamine, 1,5-naphthalenediamine, 2,6-naphthalenediamine, bis [4-(4-aminophenoxy)phenyl]sulfone, bis(3-aminophenoxyphenyl) sulfone, bis(4-aminophenoxy) biphenyl, bis [4-(4-aminophenoxy)phenyl]ether, 1,4-bis(4-aminophenoxy)benzene, the forgoing compounds including an aromatic ring substituted with alkyl group or a halogen, or a combination thereof, but are not limited thereto.

Examples of the alicyclic diamine may be 1,2-cyclohexyl diamine, 1,3-cyclohexyl diamine, or a combination thereof, but are not limited thereto.

Examples of the silicon diamine may be bis(4-aminophenyl)dimethylsilane, bis(4-aminophenyl)tetramethylsiloxane, bis(p-aminophenyl)tetramethyldisiloxane, bis(γ-aminopropyl)tetramethyldisiloxane, 1,4-bis(γ-aminopropyldimethylsilyl)benzene, bis(4-aminobutyl)tetramethyldisiloxane, bis(γ-aminopropyl)tetraphenyldisiloxane, 1,3-bis(aminopropyl)tetramethyldisiloxane, or a combination thereof, but are not limited thereto.

In Chemical Formula 51, Y³ is a quadrivalent aromatic organic group, a quadrivalent aliphatic organic group, or a quadrivalent alicyclic organic group. Specifically, Y³ is a quadrivalent aromatic organic group or a quadrivalent alicyclic organic group.

Y³ may be a moiety derived from an aromatic acid dianhydride or an alicyclic acid dianhydride. Herein, the aromatic acid dianhydride and the alicyclic acid dianhydride may be used alone or in a combination of one or more.

Examples of the aromatic acid dianhydride may be benzophenone tetracarboxylic dianhydride such as pyromellitic dianhydride; benzophenone-3,3′,4,4′-tetracarboxylic dianhydride, and the like; oxydiphthalic dianhydride such as 4,4′-oxydiphthalic dianhydride; bisphthalic dianhydride such as 3,3′,4,4′-biphthalic dianhydride; (hexafluoroisopropylidene)diphthalic dianhydride such as 4,4′-(hexafluoroisopropylidene)diphthalic dianhydride; naphthalene-1,4,5,8-tetracarboxylic dianhydride; 3,4,9,10-perylenetetracarboxylic dianhydride, and the like, but are not limited thereto.

Examples of the alicyclic acid dianhydride may be 1,2,3,4-cyclobutanetetracarboxylic dianhydride, 1,2,3,4-cyclopentanetetracarboxylic dianhydride, 5-(2,5-dioxotetrahydrofuryl)-3-methyl-cyclohexane-1,2-dicarboxylic anhydride, 4-(2,5-dioxotetrahydrofuran-3-yl)-tetralin-1,2-dicarboxylic anhydride, bicyclooctene-2,3,5,6-tetracarboxylic dianhydride, bicyclooctene-1,2,4,5-tetracarboxylic dianhydride, and the like, but are not limited thereto.

### (B) Photopolymerizable Compound

The photosensitive resin composition according to one or more embodiments may further include a photopolymerizable compound. The photopolymerizable compound may be a single compound and/or a (e.g., any suitable) mixture of two different compounds.

The photopolymerizable compound may be a compound including at least two functional groups each represented by Chemical Formula 3.

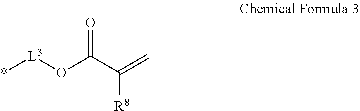

In Chemical Formula 3,
R⁸ may be hydrogen or a substituted or unsubstituted C1 to C10 alkyl group, and
L³ is a single bond or a substituted or unsubstituted C1 to C10 alkylene group.

For example, in one or more embodiments, the compound containing at least two functional groups each represented by Chemical Formula 3 may include 2 to 6 functional groups represented by Chemical Formula 3. In these embodiments, sufficient polymerization occurs during exposure in the pattern formation process to form a pattern with excellent or suitable heat resistance, light resistance, and chemical resistance.

For example, in one or more embodiments, the compound containing at least two functional groups each represented by Chemical Formula 3 may be a compound represented by any one selected from among Chemical Formula 4 to Chemical Formula 6, but embodiments of the present disclosure are not necessarily limited thereto.

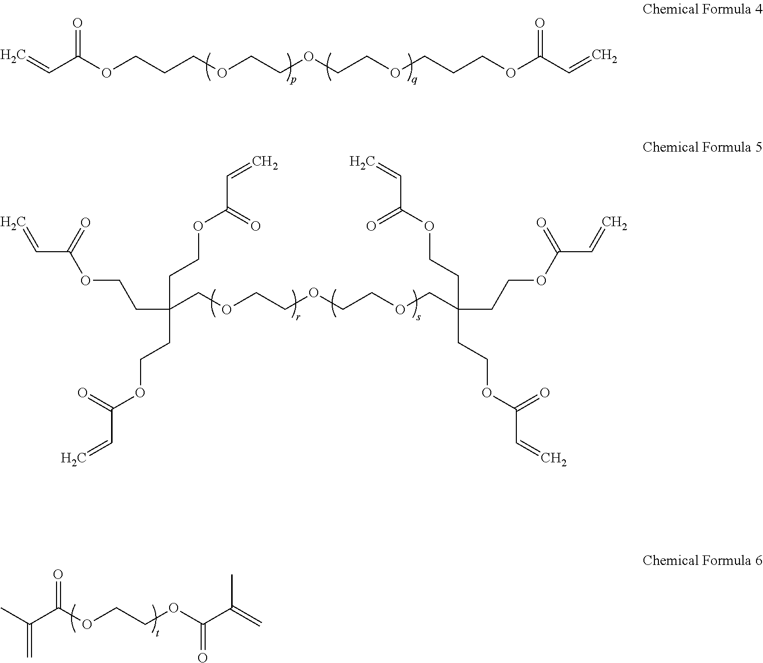

In Chemical Formula 4 to Chemical Formula 6, p, q, r, s, and t may each independently be an integer of 1 to 10.

If (e.g., when) the photopolymerizable compound is a mixture of two different compounds, the other one of the two compounds may be a mono- or multi-functional ester compound of (meth)acrylic acid having at least one ethylenically unsaturated double bond.

The mono- or multi-functional ester compound of (meth)acrylic acid having at least one ethylenically unsaturated double bond may be, for example, ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy (meth)acrylate, ethylene glycol monomethyl ether(meth)acrylate, trimethylolpropane tri(meth)acrylate, tris[(meth)acryloyloxyethyl] phosphate, novolac epoxy (meth)acrylate, or a (e.g., any suitable) combination thereof.

Commercially available products of the monofunctional or multifunctional ester compound of (meth)acrylic acid having at least one ethylenically unsaturated double bond are as follows. Non-limiting examples of the mono-functional ester of (meth)acrylic acid may include Aronix M-101®, M-111®, M-114® (Toagosei Chemistry Industry Co., Ltd.); KAYARAD TC-110S®, TC-120S® (Nippon Kayaku Co., Ltd.); V-158®, V-2311® (Osaka Organic Chemical Ind., Ltd.), and/or the like. Non-limiting examples of a di-functional ester of (meth)acrylic acid may include Aronix M-210®, M-240®, M-6200® (Toagosei Chemistry Industry Co., Ltd.), KAYARAD HDDA®, HX-220®, R-604® (Nippon Kayaku Co., Ltd.), V-260®, V-312®, V-335 HP® (Osaka Organic Chemical Ind., Ltd.), and/or the like. Non-limiting examples of a tri-functional ester of (meth)acrylic acid may include Aronix M-309®, M-400®, M-4050, M-450®, M-7100®, M-8030®, M-8060® (Toagosei Chemistry Industry Co., Ltd.), KAYARAD TMPTA®, KAYARAD DPCA-20®, KAYARAD DPCA-30®, KAYARAD DPCA-600, KAYARAD DPCA-120® (Nippon Kayaku Co., Ltd.), V-295®, V-300®, V-360®, V-GPT®, V-3PA®, V-400® (Osaka Yuki Kayaku Kogyo Co. Ltd.), and/or the like. These may be used alone or as a mixture of two or more.

The photopolymerizable compound may be used after being treated with an acid anhydride to provide better developability.

The photopolymerizable compound may be included in an amount of about 5 parts by weight to about 20 parts by weight, for example about 7 parts by weight to about 15 parts by weight, based on 100 parts by weight of the photosensitive resin composition. If the photopolymerizable compound is included within the above range, curing occurs sufficiently, reliability is excellent or suitable, heat resistance, light resistance, and chemical resistance of the pattern are improved, and resolution and adhesion are also improved.

### (C) Photoinitiator

The photosensitive resin composition according to one or more embodiments includes a photoinitiator represented by Chemical Formula 1.

For example, in one or more embodiments, in Chemical Formula 1, R¹ and R³ may be the same as each other. For example, in one or more embodiments, R¹ and R³ may each independently be a substituted or unsubstituted C6 to C20 aryl group.

For example, in one or more embodiments, R² may be a substituted or unsubstituted C1 to C20 alkyl group or a substituted or unsubstituted C3 to C20 cycloalkyl group.

In Chemical Formula 1, if (e.g., when) R¹ to R³ are as above, pattern formation may be more easily controlled or selected and may also be advantageous or beneficial in increasing the resolution of the pattern.

For example, in one or more embodiments, the photoinitiator represented by Chemical Formula 1 may include at least one selected from among compounds represented by Chemical Formula 1-1 to Chemical Formula 1-3, but embodiments of the present disclosure are not necessarily limited thereto.

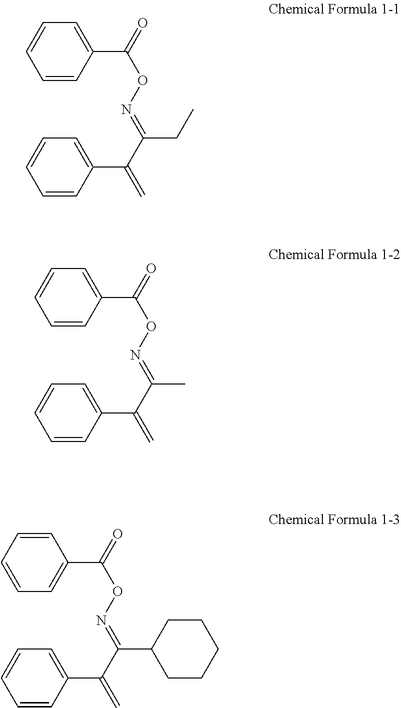 [SMILES: C=C(/C(CC)=N/OC(=O)c1ccccc1)c1ccccc1 ; C=C(/C(C)=N/OC(=O)c1ccccc1)c1ccccc1 ; C=C(/C(=N/OC(=O)c1ccccc1)C1CCCCC1)c1ccccc1]

For example, in one or more embodiments, the photoinitiator represented by Chemical Formula 1 may be included in an amount of about 1 part by weight to about 5 parts by weight, for example about 1 part by weight to about 3 parts by weight, based on 100 parts by weight of the photosensitive resin composition. If the photoinitiator represented by Chemical Formula 1 is included within the above range, photopolymerization may sufficiently occur, resulting in excellent or suitable sensitivity and improved transmittance.

In one or more embodiments, the photosensitive resin composition may further include other types (kinds) of photoinitiators in addition to the photoinitiator (oxime-based photoinitiator) represented by Chemical Formula 1. Other types (kinds) of photoinitiators may include, for example, an acetophenone-based compound, a benzophenone-based compound, a thioxanthone-based compound, a benzoin-based compound, a triazine-based compound, and/or the like.

Non-limiting examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloroacetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and/or the like.

Non-limiting examples of the benzophenone-based compound may be benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and/or the like.

Non-limiting examples of the thioxanthone-based compound may be thioxanthone, 2-chlorothioxanthone, 2-methylthioxanthone, isopropyl thioxanthone, 2,4-diethyl thioxanthone, 2,4-diisopropyl thioxanthone, and/or the like.

Non-limiting examples of the benzoin-based compound may be benzoin, benzoin methyl ether, benzoin ethyl ether, benzoin isopropyl ether, benzoin isobutyl ether, benzyl dimethyl ketal, and/or the like.

Non-limiting examples of the triazine-based compound may be 2,4,6-trichloro-s-triazine, 2-phenyl 4,6-bis(trichloromethyl)-s-triazine, 2-(3′, 4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloromethyl)-s-triazine, bis(trichloromethyl)-6-styryl-s-triazine, 2-(naphth-1-yl)-4,6-bis(trichloromethyl)-s-triazine, 2-(4-methoxynaphth-1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and/or the like.

In addition to the above compounds, the photoinitiator may include a carbazole-based compound, a diketone-based compound, a sulfonium borate-based compound, a diazo-based compound, an imidazole-based compound, a biimidazole-based compound, and/or a fluorene-based compound.

### (D) Solvent

The solvent may be a material that is compatible with, but does not react with, the resin, the photopolymerizable compound, and the photoinitiator.

Non-limiting examples of the solvent may include alcohols such as methanol, ethanol, and/or the like; ethers such as dichloroethylether, n-butylether, diisoamylether, methylphenylether, tetrahydrofuran, and/or the like; glycolethers such as ethylene glycolmonomethylether, ethylene glycolmonoethylether, ethylene glycoldimethylether, and/or the like; cellosolveacetates such as methylcellosolveacetate, ethylcellosolveacetate, diethylcellosolveacetate, and/or the like; carbitols such as methylethylcarbitol, diethylcarbitol, diethylene glycolmonomethylether, diethylene glycolmonoethylether, diethylene glycoldimethylether, diethylene glycolethylmethylether, diethylene glycoldiethylether, and/or the like; propylene glycolalkyletheracetates such as propylene glycolmethyletheracetate, propylene glycolpropyletheracetate, and/or the like; aromatic hydrocarbons such as toluene, xylene, and/or the like; ketones such as methylethylketone, cyclohexanone, 4-hydroxy-4-methyl-2-pentanone, methyl-n-propylketone, methyl-n-butylketone, methyl-n-amylketone, 2-heptanone, and/or the like; saturated aliphatic monocarboxylic acid alkyl esters such as ethyl acetate, n-butyl acetate, isobutyl acetate, and/or the like; lactate esters such as methyl lactate, ethyl lactate, and/or the like; oxy acetic acid alkyl esters such as oxy methyl acetate, oxy ethyl acetate, oxy butyl acetate, and/or the like; alkoxy acetic acid alkyl esters such as methoxy methyl acetate, methoxy ethyl acetate, methoxy butyl acetate, ethoxy methyl acetate, ethoxy ethyl acetate, and/or the like; 3-oxypropionic acid alkyl esters such as 3-oxymethyl propionate, 3-oxyethyl propionate, and/or the like; 3-alkoxypropionic acid alkyl esters such as 3-methoxymethyl propionate, 3-methoxyethyl propionate, 3-ethoxyethyl propionate, 3-ethoxymethyl propionate, and/or the like; 2-oxypropionic acid alkyl esters such as 2-oxymethyl propionate, 2-oxyethyl propionate, 2-oxypropyl propionate, and/or the like; 2-alkoxypropionic acid alkyl esters such as 2-methoxymethyl propionate, 2-methoxyethyl propionate, 2-ethoxyethyl propionate, 2-ethoxymethyl propionate, and/or the like; 2-oxy-2-methylpropionic acid esters such as 2-oxy-2-methylmethyl propionate, 2-oxy-2-methylethyl propionate, and/or the like; monooxy monocarboxylic acid alkyl esters of 2-alkoxy-2-methyl alkyl propionates such as 2-methoxy-2-methylmethyl propionate, 2-ethoxy-2-methylethyl propionate, and/or the like; esters such as 2-hydroxyethyl propionate, 2-hydroxy-2-methylethyl propionate, hydroxy ethyl acetate, 2-hydroxy-3-methyl methyl butanoate, and/or the like; ketonate esters such as ethyl pyruvate, and/or the like. Additionally, a high boiling point solvent such as N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, 3-methyl benzoate, ethylene carbonate, propylene carbonate, phenyl cellosolve acetate, and/or the like may be also used.

The solvent may be included in an amount of about 40 parts by weight to about 80 parts by weight based on 100 parts by weight of the photosensitive resin composition. If the solvent is included within the range, the photosensitive resin composition has appropriate or suitable viscosity, resulting in excellent or suitable processability when manufacturing photosensitive resin layers.

### (E) Other Additives

The photosensitive resin composition according to one or more embodiments may further include other additives.

The photosensitive resin composition may include a diacid (e.g., malonic acid, and/or the like), an alkanolamine (e.g., 3-amino-1,2-propanediol, and/or the like), a photosensitizer, an antioxidant, an adhesion (promoting) agent, a leveling agent, a silane coupling agent, a surfactant, an epoxy compound, a thermal latent acid generator, a development controlling agent, a curing agent, and/or a (e.g., any suitable) combination thereof, and/or the like, to prevent or reduce stains or spots during coating, to provide leveling properties, or to prevent or reduce the creation of residues due to non-development. An amount of these additives used may be adjusted depending on the desired or suitable physical properties.

For example, in one or more embodiments, if the photosensitive resin composition further includes the photosensitizer, the photosensitizer may be included in a smaller amount than the photoinitiator represented by Chemical Formula 1. Additionally, in addition to the photosensitizer, the photosensitive resin composition according to one or more embodiments may further include an antioxidant, and in these embodiments, the antioxidant may be included in a smaller amount than the photosensitizer. If the amounts of the photoinitiator represented by Chemical Formula 1, the photosensitizer, and the antioxidant are each controlled or selected as above, it may be more advantageous or beneficial in terms of pattern formation and high resolution.

For example, in one or more embodiments, the photosensitive resin composition may further include a silane coupling agent. The silane coupling agent may have a reactive substituent such as a vinyl group, carboxyl group, methacryloxy group, isocyanate group, or epoxy group to improve adhesion to the substrate, and has a different structure from a silane compound without a reactive substituent.

Non-limiting examples of the silane coupling agent may include trimethoxysilylbenzoic acid, γ-methacryloxypropyltrimethoxysilane, vinyltriacetoxysilane, vinyltrimethoxysilane, γ-isocyanatepropyltriethoxysilane, γ-glycidoxypropyltrimethoxysilane, β-(3,4-epoxycyclohexyl)ethyltrimethoxysilane, and/or the like. These may be used alone or in a mixture of two or more.

The silane coupling agent may be included in an amount of about 0.01 parts by weight to about 10 parts by weight based on 100 parts by weight of the photosensitive resin composition. If the silane coupling agent is included within the above range, adhesion, storage capability, and/or the like are improved.

For example, in one or more embodiments, the surfactant may be further added to prevent or reduce film thickness unevenness or improve developability, and may include a fluorine-based surfactant and/or a silicone-based surfactant.

Non-limiting examples of the fluorine-based surfactant may be a commercial fluorine-based surfactant such as BM-1000®, BM-1100®, and/or the like of BM Chemie Inc.; MEGAFACE F 142D®, MEGAFACE F 172®, MEGAFACE F 173®, MEGAFACE F 183®, MEGAFACE F 554®, and/or the like of Dainippon Ink Kagaku Kogyo Co., Ltd.; FULORAD FC-135®, FULORAD FC-170C®, FULORAD FC-430®, FULORAD FC-431® and/or the like of SUMITOMO 3M Co., Ltd.; SURFLON S-112®, SURFLON S-113®, SURFLON S-131®, SURFLON S-141®, SURFLON S-145®, and/or the like of Asahi Glass Co., Ltd.; SH-28PAR, SH-190®, SH-1933, SZ-6032®, SF-8428®, and/or the like of Toray Silicone Co., Ltd.

The silicone-based surfactant may be a commercial silicone-based surfactant such as BYK-307, BYK-333, BYK-361N, BYK-051, BYK-052, BYK-053, BYK-067A, BYK-077, BYK-301, BYK-322, BYK-325, BYK-378, and/or the like of BYK Chem.

The surfactant may be used in an amount of about 0.001 parts by weight to about 5 parts by weight based on 100 parts by weight of the photosensitive resin composition. If the surfactant is included within the above range, coating uniformity may be ensured, stains cannot occur, and wetting on ITO substrates or glass substrates, Si wafers or SiNₓ wafers, and Cu substrates may be improved.

In one or more embodiments, the photosensitive resin composition may further include an epoxy compound to improve adhesion and/or the like with a substrate. Non-limiting examples of the epoxy compound may include a phenol novolac epoxy compound, a tetramethyl biphenyl epoxy compound, a bisphenol A epoxy compound, an alicyclic epoxy compound, and/or a (e.g., any suitable) combination thereof.

The epoxy compound may be used in an amount of about 0.01 part by weight to about 5 parts by weight based on 100 parts by weight of the resin composition. When the epoxy compound is included within the above range, storage properties, adhesive force, and other properties may be improved.

In one or more embodiments, the photosensitive resin composition may further include a thermal latent acid generator. Examples of the thermal latent acid generator may include arylsulfonic acids such as p-toluenesulfonic acid and benzenesulfonic acid; perfluoroalkylsulfonic acids such as trifluoromethanesulfonic acid, trifluorobutanesulfonic acid, and/or the like; alkylsulfonic acids such as methanesulfonic acid, ethanesulfonic acid, butanesulfonic acid, and/or the like; and/or a (e.g., any suitable) combination thereof, but embodiments of the present disclosure are not limited thereto.

Furthermore, in one or more embodiments, the photosensitive resin composition may include other additives such as a stabilizer, and/or the like in a set or predetermined amount unless they deteriorate properties of the photosensitive resin composition.

According to one or more embodiments of the present disclosure, provided is a photosensitive resin layer, such as a semiconductor redistribution layer insulating layer, which is manufactured by exposing, developing, and curing the aforementioned photosensitive resin composition.

According to one or more embodiments, the photosensitive resin layer (semiconductor redistribution layer insulating layer) manufacturing method is as follows.

### (1) Coating and Film Formation

The photosensitive resin composition may be coated to have a desired or suitable thickness on a substrate such as a glass substrate or ITO substrate, a Si wafer or a SiNₓ wafer, a Cu substrate, and/or the like which undergoes a predetermined or desired pretreatment, using a spin or slit coating method, a roll coating method, a screen-printing method, an applicator method, and/or the like, and then is heated at about 70° C. to about 150° C. for about 1 minute to 10 minutes to remove a solvent and thereby to form a film (e.g., a photosensitive resin film).

### (2) Exposure

After providing a mask for forming a necessary or desired pattern on the obtained photosensitive resin layer, exposure may be performed by irradiating an actinic ray of 200 nm to 500 nm. As a light source used for irradiation, a low-pressure mercury lamp, a high-pressure mercury lamp, an ultra-high pressure mercury lamp, a metal halide lamp, an argon gas laser, and/or the like, may be used, and in some embodiments, an X-ray, an electron beam, and/or the like may be used.

The exposure dose varies depending on the type or kind and mixing amount of each component of the composition, and a dry film thickness of the photosensitive resin film, but is less than 500 mJ/cm² (based on a 365 nm sensor) if (e.g., when) using a high-pressure mercury lamp.

### (3) Development

In the development method, following the exposure step (e.g., act or task), an alkali aqueous solution or an organic solvent may be used as a developer to dissolve and remove unnecessary parts (e.g., unexposed parts), leaving only the exposed parts remaining to form a pattern (e.g., an image pattern or a latent image pattern).

### (4) Post-Processing

There is a post-heating process to obtain a pattern excellent or suitable in terms of heat resistance, light resistance, adhesion, crack resistance, chemical resistance, high strength, and storage stability of the image pattern obtained by development in the above process. For example, after development, it may be heated in a nitrogen atmosphere in an oven at 200° C. to 400° C. for more than 1 hour.

According to one or more embodiments of the present disclosure, a semiconductor device including the photosensitive resin layer (semiconductor redistribution layer insulating layer) is provided.

Hereinafter, examples of the present disclosure will be described. However, the following examples are mere examples of the disclosure to illustrate certain aspects of the disclosure, and the disclosure is not limited by the following examples.

### EXAMPLES

### Synthesis Example 1: Synthesis of Polyamic Ester-Based (Polyimide Precursor) Resin

While passing nitrogen through a four-necked flask equipped with a stirrer, a temperature controller, a nitrogen gas injection device, and a cooler, 0.58 mol of a dianhydride monomer represented by Chemical Formula A and 1.22 mol of 2-hydroxyethylmethacrylate (HEMA) were added to 600 g of γ-butyrolactone (GBL), and while stirring at room temperature, 1.16 mol of pyridine was added thereto, obtaining a reaction mixture. After performing a reaction for 16 hours at room temperature and decreasing the temperature to −10° C., a solution prepared by dissolving 250 g of GBL in 1.17 mol of dicyclohexylcarbodiimide (DCC) was added thereto in a dropwise fashion over 30 minutes. After additionally stirring the mixture for 5 minutes, a solution of 0.54 mol of a diamine monomer represented by Chemical Formula B and 300 g of GBL was slowly added thereto for a period of 40 minutes and then, additionally stirred for 2 hours. After performing a reaction at room temperature for 1 hour, 30 g of ethanol was added thereto and then, stirred for 1 hour. Subsequently, GBL was added thereto, until the reaction solution had a solid content (e.g., amount) of 18%, and then, added to 3 liters of ethanol, obtaining precipitates. The polymer was filtered therefrom and dissolved in 1.5 liters of tetrahydrofuran (THF) and then, added in a dropwise fashion to 30 liters of water to produce precipitates, which were vacuum-dried. The obtained product was dried under a reduced pressure at 50° C. for 24 hours or more, preparing a polyamic ester-based resin including a structural unit represented by Chemical Formula SE-1.

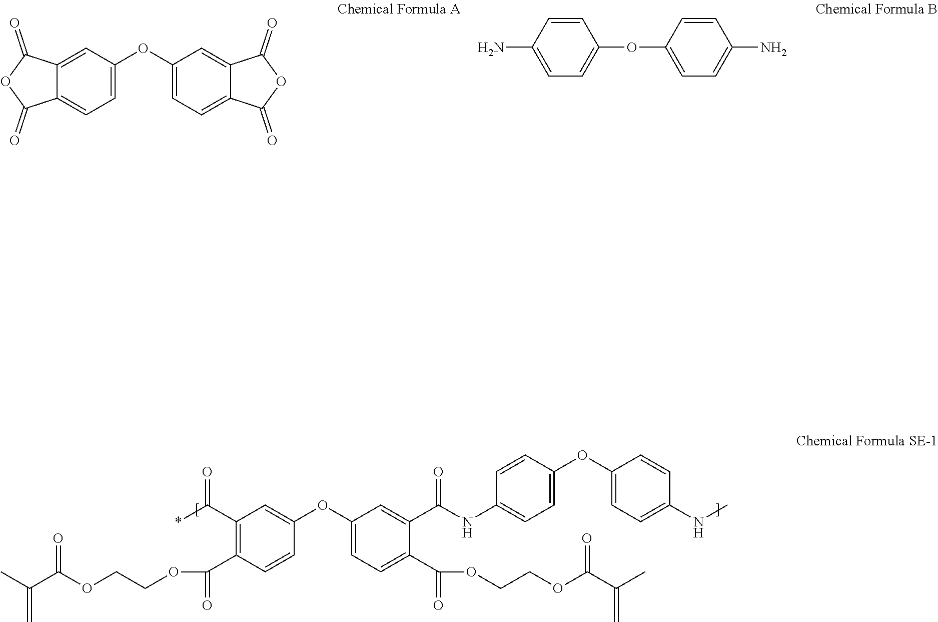

### Preparation of Photosensitive Resin Composition

Each of the photosensitive resin compositions according to Examples 1 to 6 and Comparative Examples 1 to 4 was prepared according to respective composition shown in Table 1. For example, after adding a solvent to the above polyamic ester-based resin, a photopolymerizable monomer, a photoinitiator, and other additives were added thereto and then, sufficiently stirred. Subsequently, the mixture was filtered with a 0.45 μm polypropylene resin filter, obtaining a negative type or kind photosensitive resin composition.

TABLE 1

| | | Comp. | Comp. | Comp. | Comp. | | | | | | |
|---|---|---|---|---|---|---|---|---|---|---|---|
| | | Ex. 1 | Ex. 2 | Ex. 3 | Ex. 4 | Ex. 1 | Ex. 2 | Ex. 3 | Ex. 4 | Ex. 5 | Ex. 6 |
| (A) Resin | | 34.298 | 33.818 | 33.818 | 32.384 | 31.133 | 32.384 | 32.384 | 32.384 | 32.384 | 31.133 |
| (B) Photopolymerizable | | 3.811 | 3.758 | 3.758 | 3.598 | 3.459 | 3.598 | 3.598 | 3.598 | 3.598 | 3.459 |
| compound | | | | | | | | | | | |
| (C) | (C-1) | 0.381 | 0 | 0 | 0 | 0 | 0 | 0 | 0 | 0 | 0 |
| Photoinitiator | (C-2) | 0 | 0.939 | 0 | 0 | 0 | 0 | 0 | 0 | 0 | 0 |
| | (C-3) | 0 | 0 | 0.939 | 0 | 0 | 0 | 0 | 0 | 0 | 0 |
| | (C-4) | 0 | 0 | 0 | 1.619 | 0 | 0 | 0 | 0 | 0 | 0 |
| | (C-5) | 0 | 0 | 0 | 0 | 4.151 | 1.619 | 0 | 0 | 0.971 | 5.034 |
| | (C-6) | 0 | 0 | 0 | 0 | 0 | 0 | 1.619 | 0 | 0 | 0 |
| | (C-7) | 0 | 0 | 0 | 0 | 0 | 0 | 0 | 1.619 | 0 | 0 |
| Photosensitizer | | 0.095 | 0.094 | 0.094 | 1.079 | 0 | 1.079 | 1.079 | 1.079 | 1.727 | 0.883 |
| Antioxidant | | 0.572 | 0.564 | 0.564 | 0.54 | 0.519 | 0.54 | 0.54 | 0.54 | 0.54 | 0.519 |
| Adhesion promoting agent/ | | 1.143 | 1.127 | 1.127 | 1.079 | 1.038 | 1.079 | 1.079 | 1.079 | 1.079 | 1.038 |
| silane coupling agent | | | | | | | | | | | |
| (D) Solvent | (D-1) | 47.76 | 47.76 | 47.76 | 47.76 | 47.76 | 47.76 | 47.76 | 47.76 | 47.76 | 45.994 |
| | (D-2) | 11.94 | 11.94 | 11.94 | 11.94 | 11.94 | 11.94 | 11.94 | 11.94 | 11.94 | 11.94 |

| | | | | | | | | | | |
|---|---|---|---|---|---|---|---|---|---|---|
| Total | 100.00 | 100.00 | 100.00 | 100.00 | 100.00 | 100.00 | 100.00 | 100.00 | 100.00 | 100.00 |

(A) Resin
Resin of Synthesis Example 1
(B) Photopolymerizable compound
tetraethylene glycol dimethacrylate (Manufacturer)
(C) Photoinitiator
(C-1) NCI831
(C-2) PBG305
(C-3) SPI03 (Samyang)
(C-4) Compound represented by Chemical Formula C
(C-5) Compound represented by Chemical Formula 1-1
(C-6) Compound represented by Chemical Formula 1-2
(C-7) Compound represented by Chemical Formula 1-3

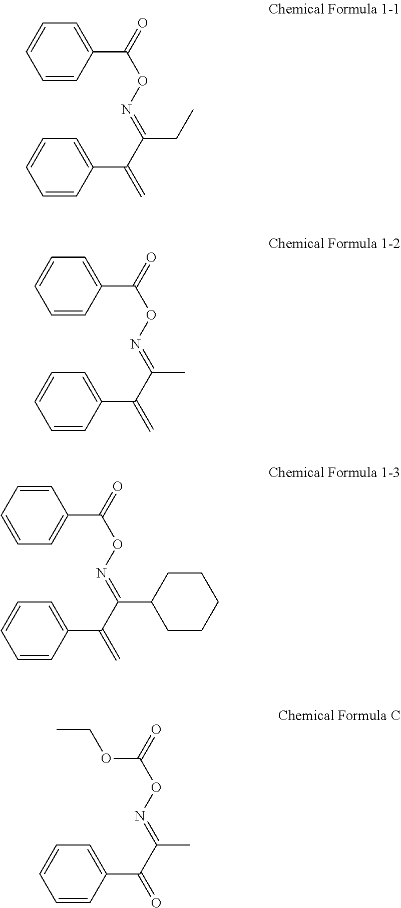 [SMILES: C=C(/C(CC)=N/OC(=O)c1ccccc1)c1ccccc1 ; C=C(/C(C)=N/OC(=O)c1ccccc1)c1ccccc1 ; C=C(/C(=N/OC(=O)c1ccccc1)C1CCCCC1)c1ccccc1 ; CCOC(=O)O/N=C(\C)C(=O)c1ccccc1]

### (D) Solvent

### (D-1) γ-Butyrolactone (GBL)

### (D-2) Dimethylsulfoxide (DMSO)

### (E) Other Additives

### Photosensitizer: N-Phenyldiethanolamine

Antioxidant: CX-1790 (Tris(4-tert-butyl-3-hydroxy-2,6-dimethylbenzyl) isocyanurate)
Adhesion promoting agent/silane coupling agent: KBM-573 (N-Phenyl-3-aminopropyltrimethoxysilane)

### Evaluation

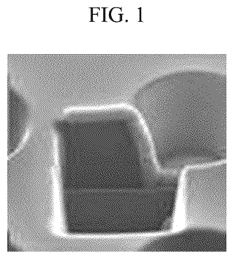

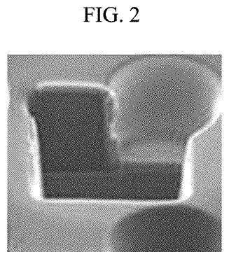

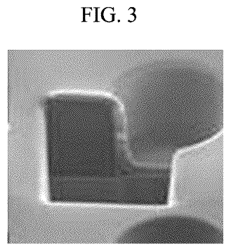

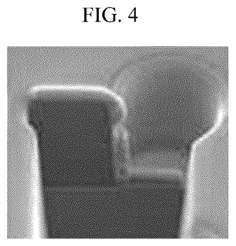

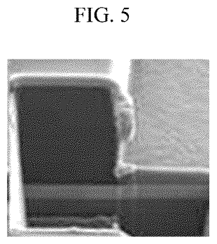

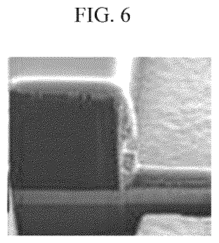

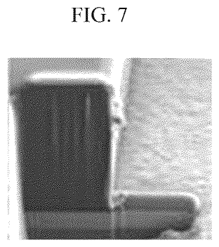

Each of the photosensitive resin compositions according to Examples 1 to 6 and Comparative Examples 1 to 4 was spin-coated on an 8-inch silicon wafer, pre-baked at about 100° C. for 4 minutes, and applied to a thickness of about 10.0 μm. Then, after cooling at room temperature for 60 seconds, light at 700 msec was irradiated with an i-line stepper (NSR-2005i10C, Nikon Inc.) to induce a photocuring reaction in the photosensitive portion. The exposed substrate was twice developed with a 100% cyclopentanone solvent at room temperature for 60 seconds in a puddle method and then, washed with a 100% propylene glycol methyl ether acetate (PGMEA) solvent for 60 seconds. Subsequently, 5, 10, and 20 μm patterns for the evaluation were checked with Critical Dimension Scanning Electron Microscope (CD-SEM) (Hitachi Ltd.), and in addition, a Taper angle was checked on a cross-section cut with focused ion beam (FIB), and the results are shown in Table 2 and in FIGS. 1 to 7. A FIB image of the cross-section was examined with naked eyes to determine if Good or Inferior.

TABLE 2

| | Limit resolution | Taper angle (°) | FIB image of |
|---|---|---|---|
| | (μm) | after development | cross-section |
| Example 1 | 5 | 70 | Good |
| Example 2 | 5 | 80 | Good |
| Example 3 | 5 | 80 | Good |
| Example 4 | 5 | 80 | Good |
| Example 5 | 10 | 85 | Good |
| Example 6 | 5 | 85 | Good |
| Comparative | 20 | >90 | Inferior |
| Example 1 | | | |
| Comparative | 10 | 90 | Inferior |
| Example 2 | | | |
| Comparative | 10 | 90 | Inferior |
| Example 3 | | | |
| Comparative | 10 | 90 | Inferior |
| Example 4 | | | |

From Table 2, each of the photosensitive resin compositions according to Examples may easily form excellent or suitable patterns and achieve high resolution, making each of them suitable for use as a composition for a semiconductor redistribution layer.

In the present disclosure, the term “comprise(s)/comprising” “include(s)/including”, or “have (has)/having” are intended to designate that the performed characteristics, numbers, step, constituted elements, or a combination thereof is present, but it should be understood that the possibility of presence or addition of one or more other characteristics, numbers, steps, constituted element, or a combination are not to be precluded in advance.

As used herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure.” Expressions such as “at least one of,” “one of,” and “selected from,” when preceding a list of elements, modify the entire list of elements and do not modify the individual elements of the list. For example, “at least one of a, b, or c,” “at least one of a, b, and/or c,” “at least one selected from a, b, and c,” “at least one selected from among a to c,” etc. may indicate only a, only b, only c, both (e.g., simultaneously) a and b, both (e.g., simultaneously) a and c, both (e.g., simultaneously) b and c, all of a, b, and c, or variations thereof. Further, the “/” utilized herein may be interpreted as “and” or as “or” depending on the situation.

In the context of the present application and unless otherwise defined, the terms “use,” “using,” and “used” may be considered synonymous with the terms “utilize,” “utilizing,” and “utilized,” respectively.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The thin film manufacturing apparatus, the semiconductor device-manufacturing apparatus such as photolithography apparatus, for example, i-line stepper, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

While the present disclosure has been described in connection with what is presently considered to be practical example embodiments, it is to be understood that the present disclosure is not limited to the disclosed embodiments, but, on the contrary, is intended to cover one or more suitable modifications and equivalent arrangements included within the spirit and scope of the appended claims and equivalents thereof. Therefore, the aforementioned embodiments should be understood to be examples but not limiting the disclosure in any way.

What is claimed is:

1. A photosensitive resin composition, comprising:
at least one resin selected from among a polyimide precursor and a polybenzoxazole precursor;
a photopolymerizable compound;
a photoinitiator represented by Chemical Formula 1; and
a solvent, 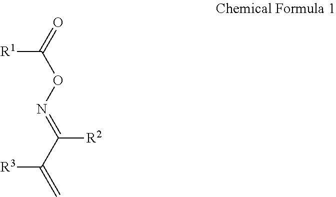
wherein in Chemical Formula 1,
R¹ to R³ are each independently hydrogen, a substituted or unsubstituted C1 to C20 alkyl group, a substituted or unsubstituted C1 to C20 alkoxy group, a substituted or unsubstituted C3 to C20 cycloalkyl group, or a substituted or unsubstituted C6 to C20 aryl group, provided that R¹ to R³ are not all hydrogens at the same time.

2. The photosensitive resin composition as claimed in claim 1, wherein
R¹ and R³ are the same as each other.

3. The photosensitive resin composition as claimed in claim 1, wherein
R¹ and R³ are each independently a substituted or unsubstituted C6 to C20 aryl group.

4. The photosensitive resin composition as claimed in claim 1, wherein
R² is a substituted or unsubstituted C1 to C20 alkyl group or a substituted or unsubstituted C3 to C20 cycloalkyl group.

5. The photosensitive resin composition as claimed in claim 1, wherein
the photoinitiator represented by Chemical Formula 1 comprises at least one selected from among compounds represented by Chemical Formula 1-1 to Chemical Formula 1-3:

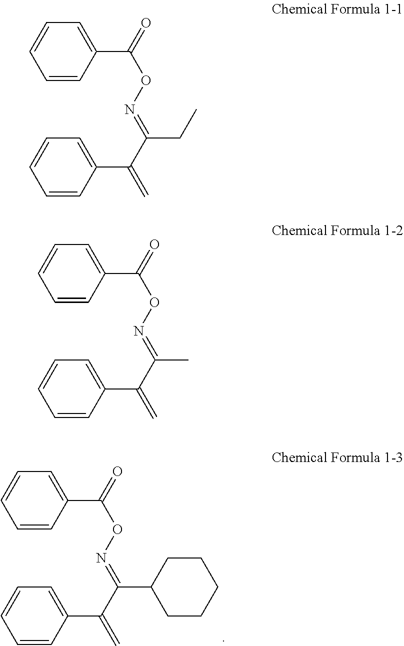 [SMILES: C=C(/C(CC)=N/OC(=O)c1ccccc1)c1ccccc1 ; C=C(/C(C)=N/OC(=O)c1ccccc1)c1ccccc1 ; C=C(/C(=N/OC(=O)c1ccccc1)C1CCCCC1)c1ccccc1]

6. The photosensitive resin composition as claimed in claim 1, wherein
the photoinitiator represented by Chemical Formula 1 is in an amount of about 1 part by weight to about 5 parts by weight based on 100 parts by weight of the photosensitive resin composition.

7. The photosensitive resin composition as claimed in claim 1, wherein
the photosensitive resin composition further comprises a photosensitizer.

8. The photosensitive resin composition as claimed in claim 7, wherein
the photosensitizer is comprised in a smaller amount than the photoinitiator represented by Chemical Formula 1.

9. The photosensitive resin composition as claimed in claim 8, wherein
the photosensitive resin composition further comprises an antioxidant, the antioxidant being in a smaller amount than the photosensitizer.

10. The photosensitive resin composition as claimed in claim 1, wherein
the photosensitive resin composition comprises, based on 100 parts by weight of the photosensitive resin composition,
about 20 parts by weight to about 40 parts by weight of the resin,
about 1 part by weight to about 10 parts by weight of the photopolymerizable compound,
about 1 part by weight to about 5 parts by weight of the photoinitiator, and
about 40 parts by weight to about 80 parts by weight of the solvent.

11. The photosensitive resin composition as claimed in claim 1, wherein
the photosensitive resin composition further comprises an additive selected from among a diacid, an alkanolamine, a leveling agent, a silane coupling agent, a surfactant, an epoxy compound, a thermal latent acid generator, and a combination thereof.

12. The photosensitive resin composition as claimed in claim 1, wherein
the photosensitive resin composition is a negative type photosensitive resin composition.

13. A photosensitive resin layer manufactured utilizing the photosensitive resin composition as claimed in claim 1.

14. The photosensitive resin layer as claimed in claim 13, wherein
the photosensitive resin layer is a semiconductor redistribution layer insulating layer.

15. A semiconductor device comprising the photosensitive resin layer as claimed in claim 13.
